(19) United States
(12) Patent Application Publication
(10) Pub. No.: US 2009/0085785 A1
(43) Pub. Date: Apr. 2, 2009

(54) DIGITAL-TO-ANALOG CONVERTER CALIBRATION FOR MULTI-BIT ANALOG-TO-DIGITAL CONVERTERS

(76) Inventors: Friedel Gerfers, Mountain View, CA (US); Li-Peng Wang, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 11/863,807

(22) Filed: Sep. 28, 2007

(51) Int. Cl. H03M 3/04

(52) U.S. Cl. 341/143

(57) ABSTRACT

According to some embodiments, a sigma-delta analog-to-digital converter includes a junction, to receive the analog signal along with a feedback signal, and a loop filter coupled to the junction. An n-bit analog-to-digital converter, coupled to the loop filter, may provide the digital output of the sigma-delta analog-to-digital converter. In addition, an n-bit feedback digital-to-analog converter, with a plurality of cells, may receive the digital output and generate the feedback signal, wherein the feedback converter is associated with at least one calibration digital-to-analog converter.

### BACKGROUND

An Analog-to-Digital Converter (ADC) may receive an analog input and provide a multi-bit digital output. For example, a sigma-delta (ΣΔ) ADC may be used to convert an analog signal into a digital one. To ensure the accuracy of such a converter, elements of the converter may need to exhibit certain characteristics (e.g., transfer characteristics). Note, however, that achieving such characteristics may be difficult given variations that occur when the converter is manufactured (e.g., variations in doping gradients or oxide t thickness). Thus, methods and apparatus that can efficiently facilitate providing appropriate characteristics for elements of an analog-to-digital converter may be desirable.

### BRIEF DESCRIPTION OF THE DRAWINGS

FIG. 1 is a block diagram of a sigma-delta analog-to-digital converter.

FIG. 2 is a block diagram of a sigma-delta analog-to-digital converter according to some embodiments.

FIG. 3 is a flow chart of a method of performing a calibration process according to some embodiments.

FIG. 4 is a block diagram of a sigma-delta analog-to-digital converter according to another embodiments.

### DETAILED DESCRIPTION

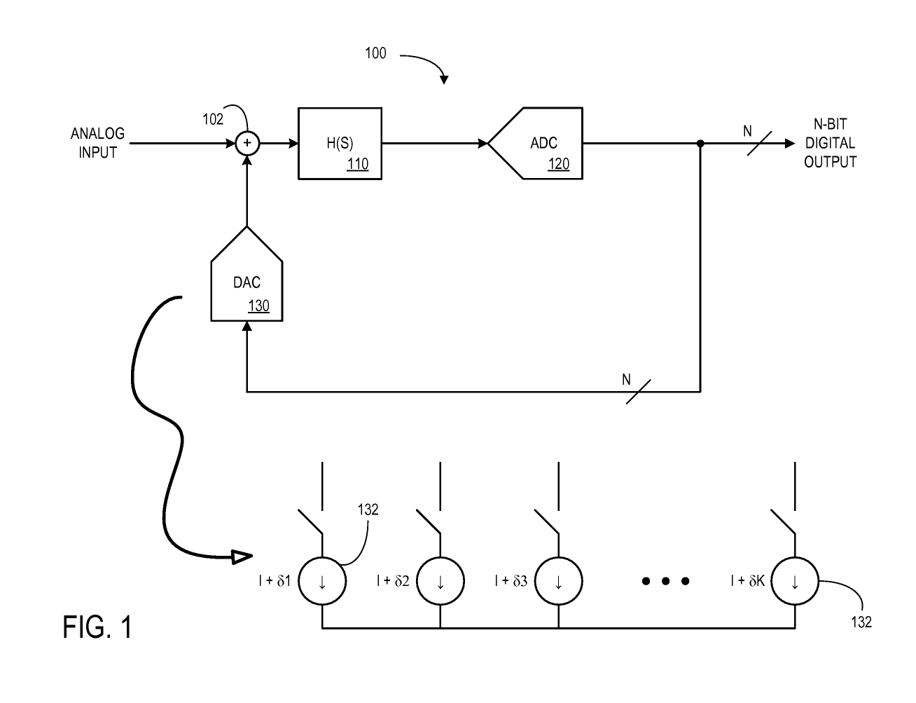

An Analog-to-Digital Converter (ADC) may receive an analog input and provide a multi-bit digital output. For example, FIG. 1 is a block diagram of a sigma-delta (ΣΔ) analog-to-digital converter 100 that may receive an analog input and generate an N-bit digital output signal. In particular, the analog input may be provided to a junction 102 (e.g., a summing junction) and the output of the junction may be provided to a loop filter H(s) 110. The output of the loop filter 110 may be provided to an internal analog-to-digital converter 120 which generates the N-bit digital output of the ΣΔ analog-to-digital converter 100. The digital output may also be provided to a feedback Digital-to-Analog Converter (DAC) 130 (e.g., having multiple cells 132) which generates a signal that is fed to the junction 102. The DAC 130 may comprise, for example, a nonlinear DAC due to mismatches within each cell 132.

Note that the overall resolution of the ΣΔ analog-to-digital converter 110 may depend on the loop filter order H(s), the number of bits of the internal analog-to-digital converter 120 and an Over Sampling Ratio (OSR) (e.g., a ratio between a sampling frequency fs and a desired bandwidth assuming accurate analog-to-digital converter and DAC components). Also note that an amount of error introduced by the internal analog-to-digital converter 120 may be attenuated by a high pass gain of a Noise Transfer Function (NTF). In contrast, errors of the feedback DAC 130 may be added to the input signal and transferred by the Signal Transfer Function (STF) with a loop gain of 1 in a band of interest. As a result, the feedback DAC 130 may need to be as accurate as the entire ΣΔ analog-to-digital converter 100. To achieve such a level of intrinsic linearity might require a large silicon area in order to handle CMOS process related errors, such as a threshold voltage mismatch of current source devices, doping gradients, and/or oxide thickness variations.

In some cases, Dynamic Element Matching (DEM) techniques may use oversampling to average out error in the time domain. Although such an approach might work efficiently for high oversampling ratios (e.g., high fidelity, narrow band audio applications), it might not be appropriate for large conversion bandwidth and/or low power consumption applications. Moreover, the DEM method might result in spectral components within the band of interest due to the large amount of switching activity per sampling cycle and may further introduce a delay in the feedback path (e.g., limiting the performance of a continuous-time or discrete-time ΣΔ analog-to-digital converter).

As another approach, a calibration technique may use reference elements, where unit cells are sequentially calibrated. Such an approach might be applied during the normal operation of the DAC 130 such that drift and/or temperature effect is reduced. This approach might, however, require that each unit cell include a storage device (typically a capacitor) which can result in a substantial current source array. Noise, current leakage, settling accuracy, and/or bandwidth limitations may further introduce accuracy and/or speed limitations. Still another approach might use an extra low speed, high accuracy analog-to-digital converter to measure the mismatches of the unit cells and a calibration DAC to correct the overall DAC 130 transfer characteristic. Such a method might therefore require a substantial amount of extra silicon area.

Instead of using an external and/or a highly accurate analog-to-digital converter for calibration, according to some embodiments elements of the ΣΔ analog-to-digital converter itself may be used to measure DAC unit cell (e.g., a mismatch associated with each cell) during a startup calibration process. As a result, the overall linearity may be adjusted by one or more calibration DACs.

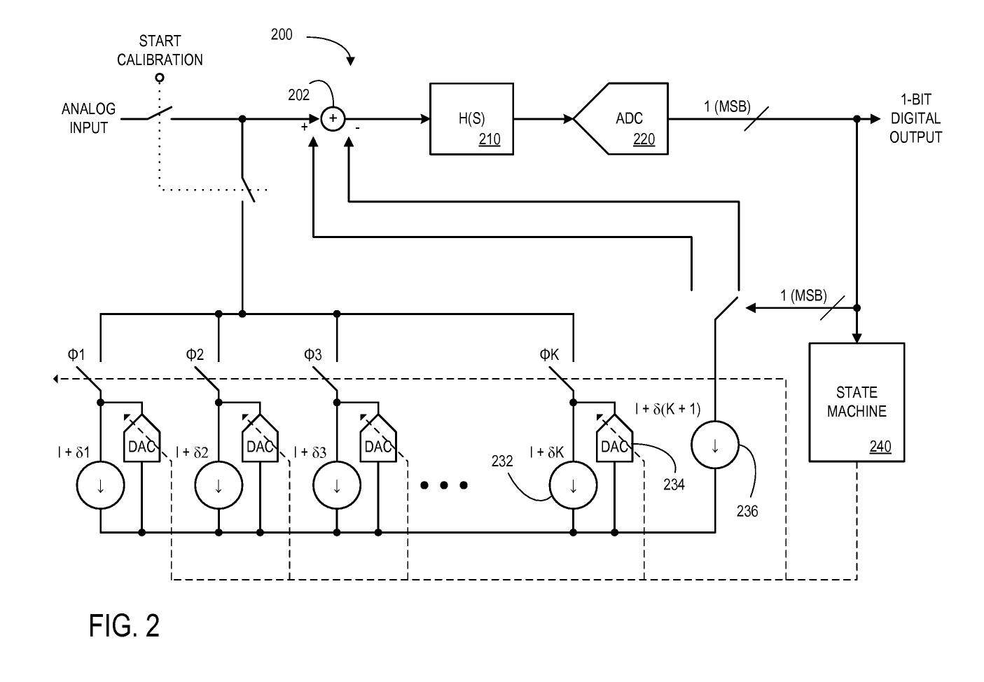

For example, FIG. 2 is a block diagram of a ΣΔ analog-to-digital converter 200 according to some embodiments that may receive an analog input and generate an n-bit digital output signal. In this case, a feedback DAC calibration procedure may use a single bit of the ΣΔ analog-to-digital converter 200 to measure DAC unit cell values and a plurality of individual calibration DACs 234. As before, the analog input is provided to a junction 202 (e.g., a summing junction) and the output of the junction may be provided to a loop filter H(s) 210. The output of the loop filter 210 may be provided to an internal analog-to-digital converter 220 which in turn generates the N-bit digital output of the ΣΔ analog-to-digital converter 200. Note that during a calibration process, only a single bit of the output (e.g., the MSB) might be used.

Each current unit cell 232 in a DAC may posses (beside a nominal value I) a “mismatch” component δi, where δi may be a random value with zero mean and a Gaussian distribution. Note that any gain error in the feedback DAC due to a modified mean value I may have a relatively minor impact on the overall ΣΔ analog-to-digital converter 200 accuracy.

To measure each DAC unit cell, the analog input signal may be switched off and each DAC unit cell signal can be used as an input signal. That is, each DAC unit cell 432 may be sequentially analyzed during a calibration process. For example, during a first step of the calibration process (Φ1=1, Φ2=0, Φ3=0 . . . ΦN=0), during a second step of the calibration process (Φ1=0, Φ2=1, Φ3=0 . . . ΦN=0), etc.

The feedback loop of the ΣΔ analog-to-digital converter 200 may be closed by an extra spear DAC unit cell 236 (or by one of the unused DAC cells). This DAC cell 236 may be, for example, driven by the Most Significant Bit (MSB) of the analog-to-digital converter 220. By using this approach, nonlinear problems in the feedback DAC may be reduced (since a two level DAC is inherently linear). The remaining error in the analysis may be attributed to a DAC offset (because a DC signal was used as an input signal).

Finally, each DAC value may be represented by a digital output sequence of the ΣΔ analog-to-digital converter 200. Since a DC value which corresponds to a mean value of the output sequence may be of interest, the data may be summed and divided by the number of points/samples (Np). Note that 2^{(M+1)} data samples may be used to get an M-bit precision DAC value (e.g., to cancel circuit and quantization noise as well as other random effects). When such a binary number of points (2^{(M+1)}) is used, the division by Np can be performed using only a shift operation such that the sum of the digital output sequence of the ΣΔ analog-to-digital converter 200 may represent the DAC value. According to this value, each calibration DAC 234 may be adjusted by a state machine 240 to achieve a required linearity. Note that components may be differentially designed, such that both positive and negative mismatches can be calibrated.

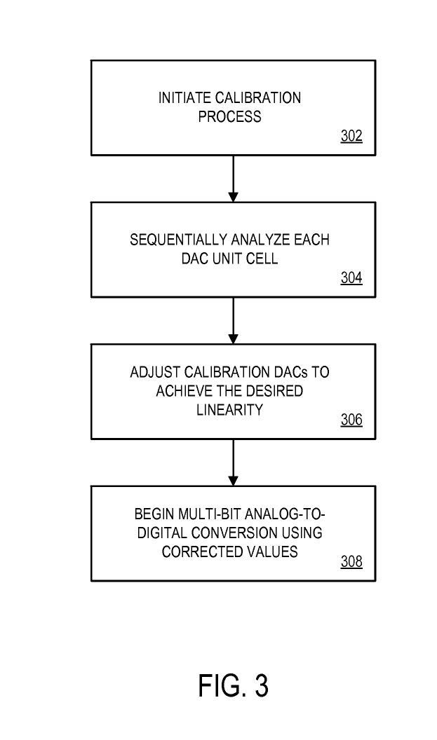

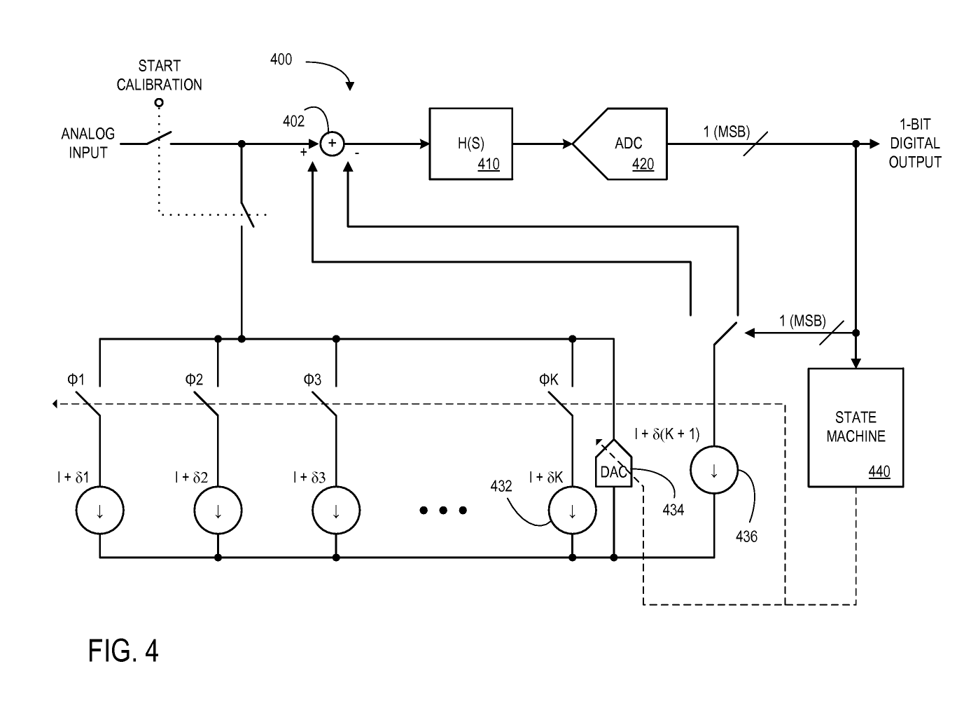

FIG. 3 is a flow chart of a method of stall optimization according to some embodiments. The flow charts described herein do not necessarily imply a fixed order to the actions, and embodiments may be performed in any order that is practicable. The method of FIG. 3 may be associated with, for example, the ΣΔ analog-to-digital converter 200 of FIG. 2 and/or FIG. 4.

At 302, a calibration process may be initiated. For example, an analog input may be removed from a ΣΔ analog-to-digital converter so that the calibration process for a feedback DAC of the ΣΔ analog-to-digital converter can be performed. At 304, each unit cell of the feedback DAC may be sequentially analyzed. For example, the process may measure a first cell (with all other cells being removed). The process may then measure the next sequential cell, etc. until measurements are obtained for all cells of the feedback DAC.

At 306, one or more calibration DACs may be adjusted to achieve a desired level of linearity. For example, the values measured at 304 may be used to calculate a corrective value for a plurality of calibration DACs (e.g., with each calibration DAC being associated with a different cell of the feedback DAC). As another example, the values measured at 304 may be used to calculate a corrective value for a global calibration DAC (e.g., the single global calibration DAC being associated with a number of different cells of the feedback DAC). At 308, multi-bit analog-to-digital conversion may begin in accordance with the corrected values of the calibration DAC(s).

Instead of using K individual calibration DACs, one for each current source, according to another embodiment, a global calibration DAC may be provided for multiple current sources. For example, FIG. 4 illustrates a ΣΔ analog-to-digital converter 400 according to such an embodiment. In this case, a feedback DAC calibration procedure may use a single bit of the ΣΔ analog-to-digital converter 200 to measure DAC unit cell values and a single, global calibration DAC 434. As before, the analog input is provided to a junction 402 (e.g., a summing junction) and the output of the junction may be provided to a loop filter H(s) 410. The output of the loop filter 410 may be provided to an internal analog-to-digital converter 420 which in turn generates the N-bit digital output of the ΣΔ analog-to-digital converter 400. Note that during a calibration process, only a single bit of the output (e.g., the MSB) might be used.

To measure each DAC unit cell, the analog input signal may be switched off and each DAC unit cell signal can be used as an input signal. That is, each DAC unit cell 432 may be sequentially analyzed during a calibration process. For example, during a first step of the calibration process (Φ1=1, Φ2=0, Φ3=0 . . . ΦN=0), during a second step of the calibration process (Φ1=0, Φ2=1, Φ3=0 . . . ΦN=0), until the last step of the calibration process (Φ1=0, Φ2=0, Φ3=0 . . . ΦN=1).

The feedback loop of the ΣΔ analog-to-digital converter 400 may be closed by an extra spear DAC unit cell 436 (or by one of the unused DAC cells). This DAC cell 436 may be, for example, driven by the MSB of the analog-to-digital converter 420. Instead of K individual calibration DACs for every current source 432, only a single, global one is provided according to this embodiment. After measuring each DAC unit cell 432, a certain calibration DAC 434 setting is calculated to obtain the required overall DAC linearity (e.g., and the calibration process may be controlled by a state machine 440 similar to the one described with respect to FIG. 2).

Note that the main error sources that may degrade the overall calibration accuracy are the offsets of the loop filter 410 and the remaining analog-to-digital converter 420 and the DAC offset (I). As a result, the calibration method may not be able measure the absolute DAC current source value. Also note, however, that multi-bit ΣΔ analog-to-digital converters may be tolerant to an overall DAC gain error—the only stringent requirement is linearity. Thus, a calibration method based on a relative comparison of each DAC unit cell may be appropriate, such that the measured DAC value (which is affected by the offsets) is adjusted by the calibration DAC or DACs, and each DAC cell may exhibit a similar measured value (which results in a DAC transfer characteristic having N-bit linearity).

As a result of some embodiments described herein, calibration techniques may not require an extremely accurate analog-to-digital converter to measure DAC cell mismatch, substantially reducing the area requirement of the overall apparatus.

The following illustrates various additional embodiments. These do not constitute a definition of all possible embodiments, and those skilled in the art will understand that many other embodiments are possible. Further, although the following embodiments are briefly described for clarity, those skilled in the art will understand how to make any changes, if necessary, to the above description to accommodate these and other embodiments and applications.

For example, although some embodiments have been described with respect particular circuits, note that embodiments may be implemented using any number of other types of circuits and components. Moreover, note that DAC cells could be measured in any order during a calibration process (e.g., the order does not need to be sequential).

The several embodiments described herein are solely for the purpose of illustration. Persons skilled in the art will recognize from this description other embodiments may be practiced with modifications and alterations limited only by the claims.

What is claimed is:

1. An apparatus, comprising:
an input to receive an analog signal; and
a sigma-delta analog-to-digital converter to receive the analog signal and to provide a multi-bit digital output, comprising:
a junction to receive the analog signal along with a feedback signal,
a loop filter coupled to the junction,
an n-bit analog-to-digital converter, coupled to the loop filter, to provide the digital output of the sigma-delta analog-to-digital converter, and
an n-bit feedback digital-to-analog converter, having a plurality of cells, to receive the digital output and generate the feedback signal, wherein the feedback converter includes at least one calibration digital-to-analog converter.

2. The apparatus of claim 1, wherein the at least one calibration digital-to-analog converter comprises a plurality of calibration digital-to-analog converters, each being associated with a cell of the feedback converter.

3. The apparatus of claim 1, wherein the calibration digital-to-analog converter comprises a single global calibration digital-to-analog converter associated with a plurality of cells.

4. The apparatus of claim 1, further comprising:
a state machine to receive at least a portion of the digital output of the sigma-delta analog-to-digital converter and to control the at least one calibration digital-to-analog converter.

5. The apparatus of claim 4, wherein the state machine receives the most significant bit of the sigma-delta analog-to-digital converter.

6. The apparatus of claim 4, wherein the state machine controls the at least one calibration digital-to-analog converter in accordance with a sequence of values measured during a calibration process.

7. The apparatus of claim 6, wherein each value in the sequence is associated with a cell of the feedback converter.

8. A method, comprising:
analyzing each cell of a feedback digital-to-analog converter in a sigma-delta analog-to-digital converter; and
adjusting at least one calibration digital-to-analog converter associated with the feedback converter as a result of said analyzing.

9. The method of claim 8, wherein said analyzing and adjusting are performed during a calibration process for the sigma-delta analog-to-digital converter.

10. The method of claim 9, wherein the calibration process includes:
closing a feedback loop of the sigma-delta analog-to-digital converter in accordance with a most significant bit output from the analog-to-digital converter.

11. The method of claim 9, wherein the calibration process includes:
removing an analog input from the sigma-delta analog-to-digital converter.

11. The method of claim 9, wherein the calibration process includes:
measuring a series of values output from the analog-to-digital converter.

12. The method of claim 11, further comprising:
determining a mean value of the series of values.

13. The method of claim 12, wherein said determining comprises:
summing the series of values; and
dividing by the sum be number of values in the series.

14. The method of claim 13, wherein said dividing comprises a shift operation.

15. The method of claim 8, wherein said adjusting comprises:
adjusting a plurality of calibration digital-to-analog converters via a state machine.

16. The method of claim 8, wherein said adjusting comprises:
adjusting a single, global calibration digital-to-analog converter via a state machine.

17. A sigma-delta analog-to-digital converter, comprising:
a summing junction;
a loop filter coupled to the summing junction;
an internal analog-to-digital converter coupled to the loop filter; and
a feedback digital-to-analog converter coupled to the internal analog-to-digital converter and to the summing junction, wherein calibration measurements for cells of the feedback converter or performed using the sigma-delta analog-to-digital converter.

18. The sigma-delta analog-to-digital converter of claim 17, further comprising a state machine coupled to the loop filter and to the feedback digital-to-analog converter.

19. The sigma-delta analog-to-digital converter of claim 17, further comprising:
a calibration control input line.

20. The sigma-delta analog-to-digital converter of claim 17, further comprising:
at least one calibration digital-to-analog converter to adjust a linearity of the sigma-delta analog-to-digital converter.
